(19) United States
(12) Patent Application Publication
(10) Pub. No.: US 2021/0335579 A1
(43) Pub. Date: Oct. 28, 2021

(54) CORRECTION METHOD AND PLASMA PROCESSING APPARATUS

(71) Applicant: TOKYO ELECTRON LIMITED, Tokyo (JP)

(72) Inventor: Inho JANG, Miyagi (JP)

(73) Assignee: TOKYO ELECTRON LIMITED, Tokyo (JP)

(21) Appl. No.: 17/237,704

(22) Filed: Apr. 22, 2021

(30) Foreign Application Priority Data
Apr. 27, 2020 (JP) 2020-077956

(51) Int. Cl. H01J 37/32

(52) U.S. Cl. CPC H01J 37/32449; H01J 2237/334; H01J 37/32183

(57) ABSTRACT

A correction method is provided. In the correction method, a detection of an impedance of a chamber is started, the chamber having therein a substrate support on which a substrate is placed. A supply of a processing gas into the chamber is started. Further, an arrival time at which the processing gas reaches the chamber from a start of the supply of the processing gas to the chamber is calculated based on a change in the detected impedance.

### CROSS-REFERENCE TO RELATED APPLICATIONS

This application claims priority to Japanese Patent Application No. 2020-077956, filed on Apr. 27, 2020, the entire contents of which are incorporated herein by reference.

### TECHNICAL FIELD

The present disclosure relates to a correction method and a plasma processing apparatus.

### BACKGROUND

Japanese Patent Application Publication No. 2016-157735 discloses a technique for applying a radio frequency (RF) power for plasma generation and an RF power for bias to a substrate support in a state where a predetermined phase difference is generated between the RF power for plasma generation and the RF power for bias, and a duty ratio of the RF power for plasma generation is controlled to be higher than or equal to a duty ratio of the RF power for bias. Further, Japanese Patent Application Publication No. 2020-4931 discloses a technique for stably and quickly switching a processing gas.

### SUMMARY

The present disclosure provides a technique for calculating an arrival time at which a processing gas reaches a chamber from the time at which a supply of the processing gas to the chamber is started.

In accordance with an aspect of the present disclosure, there is provided a correction method including: starting a detection of an impedance of a chamber having therein a substrate support on which a substrate is placed; starting a supply of a processing gas into the chamber; and calculating an arrival time at which the processing gas reaches the chamber from a start of the supply of the processing gas to the chamber based on a change in the detected impedance.

### BRIEF DESCRIPTION OF THE DRAWINGS

The objects and features of the present disclosure will become apparent from the following description of embodiments, given in conjunction with the accompanying drawings, in which:

FIG. 1 is a cross sectional view showing a schematic configuration of a plasma processing apparatus according to an embodiment;

FIG. 2 shows an example of a configuration of a matching unit and a configuration of a radio frequency (RF) power supply according to the embodiment;

FIG. 3 shows an example of a matching circuit of the matching unit according to the embodiment;

FIG. 4 shows an example of a configuration of a sensor of the matching unit according to the embodiment;

FIG. 5 shows an example of a configuration of a matching unit and a configuration of an RF power supply according to the embodiment;

FIG. 6 shows an example of a matching circuit of the matching unit according to the embodiment;

FIG. 7 shows an example of a configuration of a sensor of the matching unit according to the embodiment;

FIG. 8 shows an example of a schematic configuration of a gas supply system according to the embodiment;

FIG. 9 shows an example of schematic processes of atomic layer etching according to the embodiment;

FIG. 10 shows an example of a conventional atomic layer etching;

FIG. 11A shows an example of an impedance change;

FIG. 11B shows an example of an impedance change;

FIG. 12 shows an example of an impedance change;

FIG. 13 shows an example of a correction of a processing gas supply timing according to the embodiment;

FIG. 14 shows an example of a correction of a processing gas supply timing according to the embodiment; and

FIG. 15 shows an example of a control sequence of a correction method according to the embodiment.

### DETAILED DESCRIPTION

Hereinafter, a correction method and a plasma processing apparatus according to embodiments of the present disclosure will be described in detail with reference to the accompanying drawings. The following embodiments are not intended to limit the correction method and the plasma processing apparatus of the present disclosure.

In a plasma processing apparatus, plasma processing may be performed by switching a supply of a processing gas and switching an application of a radio frequency (RF) power. For example, an atomic layer etching (ALE) method in which a substrate is etched layer by layer has been suggested as a type of plasma processing method. In the ALE method, a film forming process of depositing deposits on a substrate and an etching process of etching a substrate using ions or radicals are repeated. The processing gas is switched between the film forming process and the etching process. In the plasma processing apparatus, switching of the supply of the processing gas is performed to start or stop the supplying of the processing gas, and since a time lag exists until the processing gas is actually supplied or stopped in the chamber after the switching, it is difficult to synchronize and control the switching of the processing gas with the switching of the RF power at a high speed. Therefore, in the conventional ALE method, a buffering process for switching is provided between the film forming process and the etching process, which leads to the increase of a processing time.

Accordingly, it is desired to have a technique capable of calculating an arrival time at which the processing gas reaches the chamber from the time at which the supply of the processing gas into the chamber is started.

### Embodiment

<Configuration of Plasma Processing Apparatus>

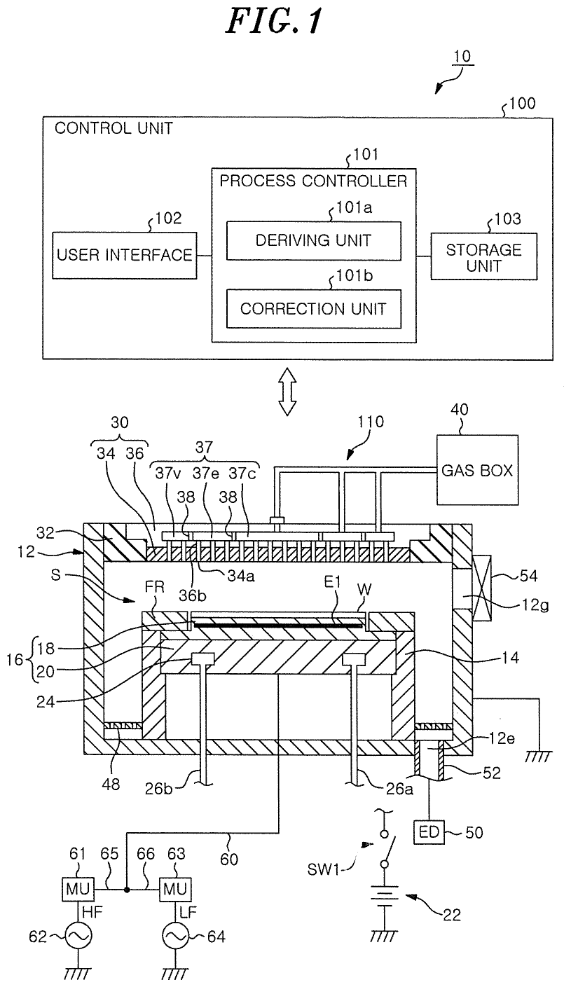

Next, an embodiment will be described. First, a plasma processing apparatus 10 according to the embodiment will be described. FIG. 1 is a cross sectional view showing a schematic configuration of the plasma processing apparatus according to the embodiment. The plasma processing apparatus 10 shown in FIG. 1 is a capacitively-coupled parallel-plate type plasma etching apparatus. The plasma processing apparatus 10 includes a substantially cylindrical chamber 12.

A substrate support 16 is disposed in the chamber 12. The substrate support 16 includes a supporting member 18 and a base 20. The supporting member 18 has an upper surface that is a substrate supporting surface on which a substrate that is a plasma processing target is placed. In the present embodiment, a wafer W that is a plasma etching target is placed as the substrate on the upper surface of the supporting member 18. The base 20 has a substantially disc shape, and a main portion thereof is made of a conductive metal such as aluminum. The base 20 serves as a lower electrode. The base 20 is supported by a support portion 14. The support portion 14 is a cylindrical member vertically extending upward from the bottom of the chamber 12.

Power feeding lines 65 and 66 are connected to the base 20 of the substrate support 16. A conductor (e.g., a power feeding rod) is disposed at a portion where the power feeding lines 65 and 66 are connected to the base 20. A radio frequency (RF) power supply 62 is electrically connected to the power feeding line 65 through a matching unit (MU) 61. An RF power supply 64 is electrically connected to the power feeding line 66 through a matching unit (MU) 63. In other words, the RF power supply 62 is electrically coupled to the lower electrode through the matching unit 61 and the power feeding line 65. The RF power supply 64 is electrically coupled to the lower electrode through the matching unit 63 and the power feeding line 66. The RF power supply 62 may not be electrically coupled to the lower electrode, and may be electrically coupled to an upper electrode to be described later through the matching unit 61. The plasma processing apparatus 1 does not necessarily include one of the set of the RF power supply 62 and the matching unit 61 and the set of the RF power supply 64 and the matching unit 63.

The RF power supply 62 is configured to output an RF power HF for generating plasma. A fundamental frequency fB1 of the RF power HF is within a range of 27 MHz to 100 MHz, e.g., 100 MHz.

The RF power supply 64 is configured to output an RF bias power LF for drawing ions in the plasma toward the wafer W. A frequency of the RF bias power LF is lower than the frequency of the RF power HF. A fundamental frequency fB2 of the RF bias power LF is within a range of 400 kHz to 13.56 MHz, e.g., 13.56 MHz.

The matching unit 61 has a circuit for matching an impedance of a load (e.g., the lower electrode (the base 20)) of the RF power supply 62 with an output impedance of the RF power supply 62. The matching unit 63 has a circuit for matching an impedance of a load (the lower electrode) of the RF power supply 64 with an output impedance of the RF power supply 64. Each of the matching units 61 and 63 is an electronically controlled matching unit. Each of the matching units 61 and 63 will be described later in detail.

The RF power HF is supplied to the base 20 through the power feeding line 65. The RF bias power LF is supplied to the base 20 through the power feeding line 66.

The support member 18 is disposed on the base 20. The support member 18 is, for example, an electrostatic chuck. The wafer W is attracted to and held on the support member 18 by an electrostatic force such as a Coulomb force. The support member 18 includes an electrode E1 for electrostatic attraction in a main body thereof that is made of ceramic. A DC power supply 22 is electrically connected to the electrode E1 through a switch SW1. The support member 18 may further include a heater for controlling a temperature of the wafer W.

A focus ring FR is disposed on an upper surface of the base 20 to surround the support member 18. The focus ring FR is provided to improve the uniformity of plasma processing. The focus ring FR is made of a material that is appropriately selected depending on the plasma processing to be performed. For example, the focus ring RF may be formed of silicon or quartz.

A coolant flow channel 24 is formed in the base 20. A coolant is supplied from a chiller unit disposed outside the chamber 12 to the coolant flow channel 24 through a pipe 26a. The coolant supplied to the coolant flow path 24 returns to the chiller unit through a pipe 26b.

An upper electrode 30 serving as a shower head for supplying a gas toward the wafer W is disposed in the chamber 12. The upper electrode 30 is disposed above the substrate support 16 to be opposed to the base 20. The base 20 and the upper electrode 30 are disposed substantially in parallel to each other. A processing space S is formed between the upper electrode 30 and the lower electrode (base 20). In the processing space S, plasma for performing the plasma processing on the wafer W is generated.

The upper electrode 30 is supported at an upper portion of the chamber 12 via an insulating shield member 32. The upper electrode 30 may include an electrode plate 34 and an electrode holder 36. The electrode plate 34 faces the processing space S. The electrode plate 34 has a plurality of gas injection holes 34a.

The electrode holder 36 is made of a conductive material such as aluminum and detachably holds the electrode plate 34. The electrode holder 36 may have a water-cooling structure. A disc-shaped gas diffusion space 37 is formed in the electrode holder 36. The gas diffusion space 37 is divided into a plurality of spaces. For example, annular partition wall members 38 are disposed in the gas diffusion space 37. In the plasma processing apparatus 10 according to the present embodiment, the gas diffusion space 37 is divided into a plurality of spaces in a radial direction by the partition wall members 38. For example, the gas diffusion space 37 is divided into three zones, i.e., gas diffusion zones 37c, 37e, and 37v, respectively corresponding to a central portion, a peripheral portion, and an outermost edge portion of the wafer W. However, the number of the zones divided in the gas diffusion space 37 is not limited to three and may be two or four or more. The gas diffusion zone 37c is a disc-shaped space. The gas diffusion zone 37e is a ring-shaped space surrounding the gas diffusion zone 37c. The gas diffusion zone 37v is a ring-shaped space surrounding the gas diffusion space 37e. A plurality of gas holes 36b respectively communicating with the gas injection holes 34a extend downward from each of the gas diffusion zones 37c, 37e, and 37v.

The plasma processing apparatus 10 includes a gas box 40 for supplying various gases used for plasma processing. Further, a gas supply system 110 for supplying the gas supplied from the gas box 40 to each of the gas diffusion zones 37c, 37e, and 37v is connected to the electrode holder 36. The gas supply system 110 will be described in detail later.

The gas supplied to each of the gas diffusion zones 37c, 37e, and 37v is injected to the processing space S through the gas holes 36b and the gas injection holes 34a. By controlling the gas box 40 and the gas supply system 110, the plasma processing apparatus 10 controls the flow rate of the processing gas injected from the gas injection holes 34a of each of the gas diffusion zones 37c, 37e, and 37v into the processing space S.

At a lower portion of the chamber 12, a gas exhaust plate 48 is disposed between the support portion 14 and an inner wall of the chamber 12. The gas exhaust plate 48 is formed by coating ceramic such as Y₂O₃ on an aluminum base, for example. The chamber 12 includes a gas outlet 12e disposed below the exhaust plate 48. An exhaust device (ED) 50 is connected to the gas outlet 12e through a gas exhaust pipe 52. The exhaust device 50 includes a vacuum pump such as a turbo molecular pump so as to reduce a pressure in the chamber 12 to a desired vacuum level. Further, a loading/unloading port 12g for a wafer W is disposed on a sidewall of the chamber 12. The loading/unloading port 12g can be opened and closed by a gate valve 54.

The operation of the plasma processing apparatus 10 configured as described above is integrally controlled by a control unit 100. The control unit 100 is, e.g., a computer, and controls the individual components of the plasma processing apparatus 10.

The control unit 100 includes a process controller 101 that has a CPU and configured to control the individual components of the plasma processing apparatus 10, a user interface 102, and a storage unit 103.

The user interface 102 includes a keyboard through which a process manager inputs instructions to manage the plasma processing apparatus 10, and a display for visualizing and displaying an operation status of the plasma processing apparatus 10.

The storage unit 103 is configured to store control programs (software) for implementing various processes performed in the plasma processing apparatus 10 under the control of the process controller 101 and/or recipes including process condition data. Further, the storage unit 103 stores, for example, parameters related to an apparatus and a process for performing plasma processing. The control programs, the recipes, and the parameters may be stored in a computer-readable computer storage medium (e.g., a hard disk, an optical disk such as a DVD, a flexible disk, a semiconductor memory, or the like). Alternatively, the control programs, the recipes, and the parameters may be stored in another device and read and used online through, e.g., a dedicated line.

The process controller 101 has an internal memory for storing programs or data. The process controller 101 reads out the control programs stored in the storage unit 103 and processes the read-out control programs. The process controller 101 functions as various processing units by executing the control programs. For example, the process controller 101 has functions of a deriving unit 101a and a correction unit 101b, which will be described later.

In the present embodiment, the case where the process controller 101 functions as various processing units will be described as an example. However, the present disclosure is not limited thereto. For example, the functions of the deriving unit 101a and the correction unit 101b may be distributed and realized by a plurality of controllers.

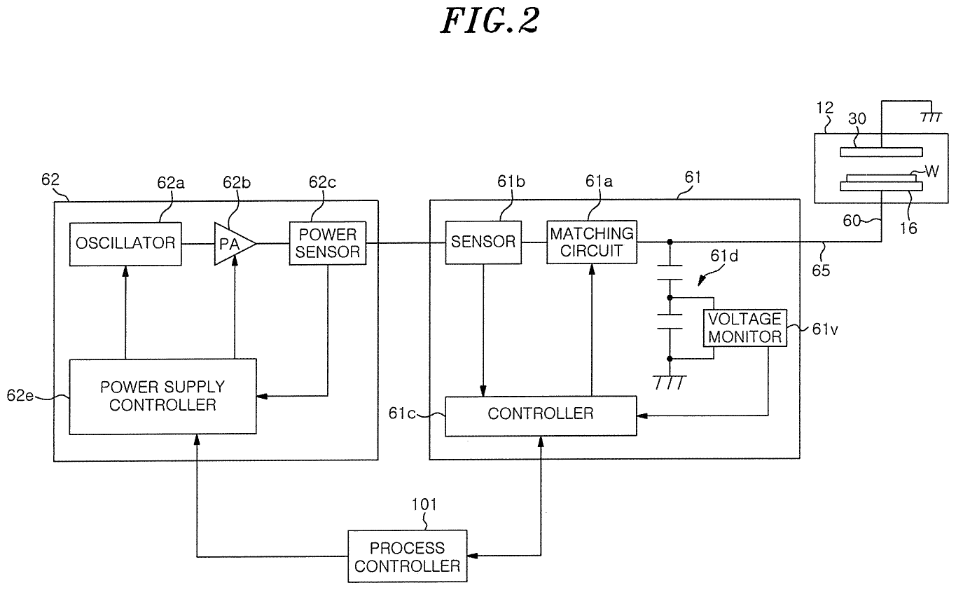

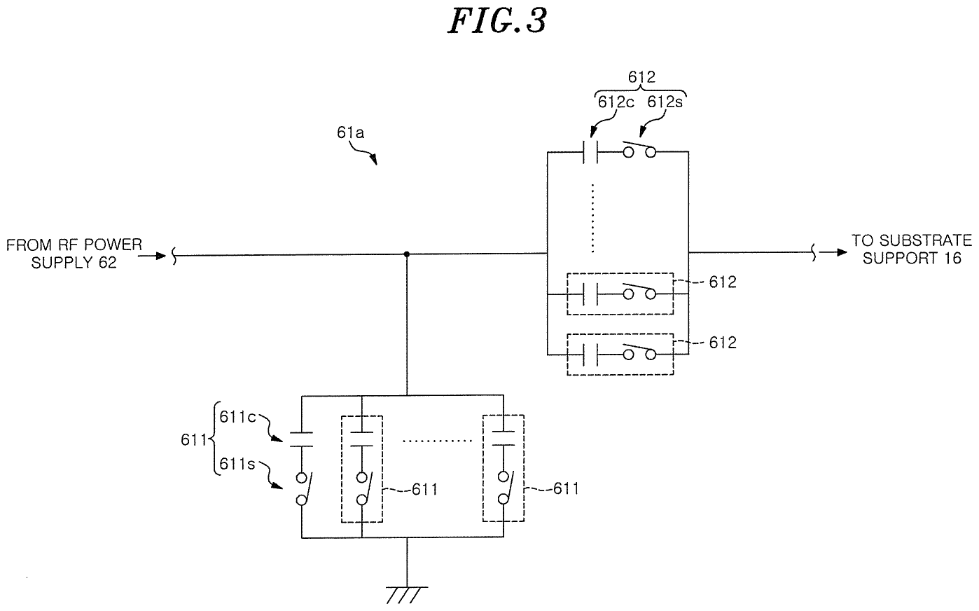

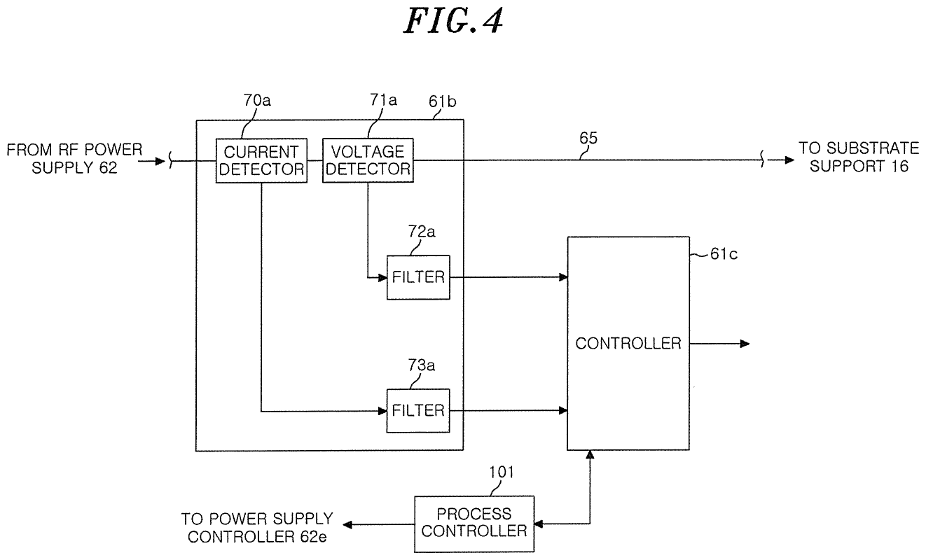

Next, a configuration of the matching unit 61 and a configuration of the RF power supply 62 according to the embodiment will be described. FIG. 2 shows an example of the configuration of the matching unit 61 and the configuration of the RF power supply 62 according to the embodiment. FIG. 3 shows an example of a matching circuit of the matching unit 61 according to the embodiment. FIG. 4 shows an example of a configuration of a sensor of the matching unit 61 according to the embodiment.

As shown in FIG. 2, the RF power supply 62 includes an oscillator 62a, a power amplifier (PA) 62b, a power sensor 62c, and a power supply controller 62e. The power supply controller 62e includes a processor such as a CPU. The power supply controller 62e controls the oscillator 62a and the power amplifier 62b by applying control signals to the oscillator 62a and the power amplifier 62b with a signal output from the process controller 101 and a signal output from the power sensor 62c.

Various control signals are sent from the process controller 101 to the power supply controller 62e. The signals sent from the process controller 101 to the power supply controller 62e include, for example, a first power level setting signal and a first frequency setting signal. The first power level setting signal specifies a power level of the RF power HF, and the first frequency setting signal specifies a set frequency of the RF power HF.

The RF power supply 62 changes the frequency of the RF power HF by changing the frequency of the oscillator 62a. The power supply controller 62e controls the oscillator 62a to output an RF signal having the set frequency specified by the first frequency setting signal. An output of the oscillator 62a is connected to an input of the power amplifier 62b. The RF signal output from the oscillator 62a is input to the power amplifier 62b. The power amplifier 62b amplifies the RF signal such that the RF power HF having the power level specified by the first power level setting signal is generated from the RF signal inputted thereto. The power amplifier 62b outputs the generated RF power HF.

The power sensor 62c is disposed at a rear stage of the power amplifier 62b. The power sensor 62c includes a directional coupler, a traveling wave detector, and a reflected wave detector. In the power sensor 62c, the directional coupler outputs a part of a traveling wave of the RF power HF to the traveling wave detector and outputs a reflected wave thereof to the reflected wave detector. A signal for specifying the frequency of the RF power HF is output from the power supply controller 62e to the power sensor 62c. The traveling wave detector of the power sensor 62c generates a measurement value of a power level of a frequency component having the same frequency as the set frequency of the RF power HF among all frequency components of the traveling wave, that is otherwise referred to as a measurement value Pf11 of a power level of the traveling wave. The measurement value Pf11 is output to the power supply controller 62e for power feedback.

The reflected wave detector of the power sensor 62c generates a measurement value of a power level of a frequency component having the same frequency as the set frequency of the RF power HF among all frequency components of the reflected wave, that is otherwise referred to as a measurement value Pr11 of the power level of the reflected wave. Further, the reflected wave detector of the power sensor 62c generates a measurement value of a total power level of all frequency components of the reflected wave, that is otherwise referred to as a measurement value Pr12 of a power level of the reflected wave. The measurement value Pr11 is output to the process controller 101 to be displayed on a monitor. The measurement value Pr12 is output to the power supply controller 62e for protection of the power amplifier 62b.

The matching unit 61 includes a matching circuit 61a, a sensor 61b, a controller 61c, a voltage divider circuit 61d, and a voltage monitor 61v. The matching circuit 61a is an electronically controlled matching circuit. As shown in FIG. 3, the matching circuit 61a has a plurality of series circuits 611 and a plurality of series circuits 612.

The series circuits 611 are connected in parallel to each other. In the example shown in FIG. 3, the series circuits 611 are connected in parallel between a ground and a node between the RF power supply 62 and the electrode of the load side (e.g., the lower electrode). Each of the series circuits 611 includes a capacitor 611c and a switching element 611s. The capacitor 611c and the switching element 611s are connected in series. The switching element 611s is, for example, a PIN diode.

The series circuits 612 are connected in parallel to each other. In the example shown in FIG. 3, the series circuits 612 are connected in parallel between the RF power supply 62 and the electrode of the load side (e.g., the lower electrode). Alternatively, the series circuits 612 may be connected in parallel between the ground and a node between the RF power supply 62 and the electrode of the load side (e.g., the lower electrode). Each of the series circuits 612 includes a capacitor 612c and a switching element 612s. The capacitor 612c and the switching element 612s are connected in series. The switching element 612s is, for example, a PIN diode. The matching circuit 61a may further include an inductor or the like.

Referring back to FIG. 2, the controller 61c includes, for example, a processor. The controller 61c is operated under the control of the process controller 101. The controller 61c uses the measurement value output from the sensor 61b.

As shown in FIG. 4, the sensor 61b includes a current detector 70a, a voltage detector 71a, a filter 72a, and a filter 73a. The voltage detector 71a detects a voltage waveform of the RF power HF transmitted on the power feeding line 65, and outputs a voltage waveform analog signal indicating the corresponding voltage waveform. This voltage waveform analog signal is input to the filter 72a. The filter 72a generates a voltage waveform digital signal by digitizing the voltage waveform analog signal input thereto. Then, the filter 72a generates a voltage waveform signal by extracting, from the voltage waveform digital signal, only a frequency component corresponding to the set frequency of the RF power HF specified by the signal output from the process controller 101. The voltage waveform signal generated by the filter 72a is output to the controller 61c. The filter 72a may be implemented by, for example, a field-programmable gate array (FPGA).

The current detector 70a detects a current waveform of the RF power HF transmitted on the power feeding line 65, and outputs a current waveform analog signal indicating the corresponding current waveform. This current waveform analog signal is input to the filter 73a. The filter 73a generates a current waveform digital signal by digitizing the current waveform analog signal input thereto. Then, the filter 73a generates a current waveform signal by extracting, from the current waveform digital signal, only a frequency component corresponding to the set frequency of the RF power HF specified by the signal output from the process controller 101. The current waveform signal generated by the filter 73a is output to the controller 61c. The filter 73a may be implemented by, for example, an FPGA.

Referring back to FIG. 2, the controller 61c is configured to obtain an impedance of the load side of the RF power supply 62 (hereinafter, referred to as “impedance Z1”). The controller 61c controls the switching elements 611s and the switching elements 612s of the matching circuit 61a to closely match the obtained impedance Z1 with the output impedance (matching point) of the RF power supply 62.

The controller 61c obtains the impedance Z1 using the voltage waveform signal generated by the filter 72a and the current waveform signal generated by the filter 73a. Specifically, the controller 61c obtains the impedance Z1 by the following equation (1):

Z1=V1/I1 Equation (1).

In equation (1), V1 indicates a voltage specified by the voltage waveform signal generated by the filter 72a, and I1 indicates a current specified by the current waveform signal generated by the filter 73a.

The controller 61c transmits the data of the obtained impedance Z1 to the process controller 101.

The matching unit 61 according to the embodiment is configured to rapidly change the impedance by electronically controlling ON/OFF of the switching elements 611s of the series circuits 611 and ON/OFF of the switching elements 612s of the series circuits 612. Accordingly, the matching unit 61 rapidly matches the impedance of the load side (e.g., the lower electrode side) of the RF power supply 62 with the output impedance of the RF power supply 62. Further, the matching unit 61 is configured to detect the impedance Z1.

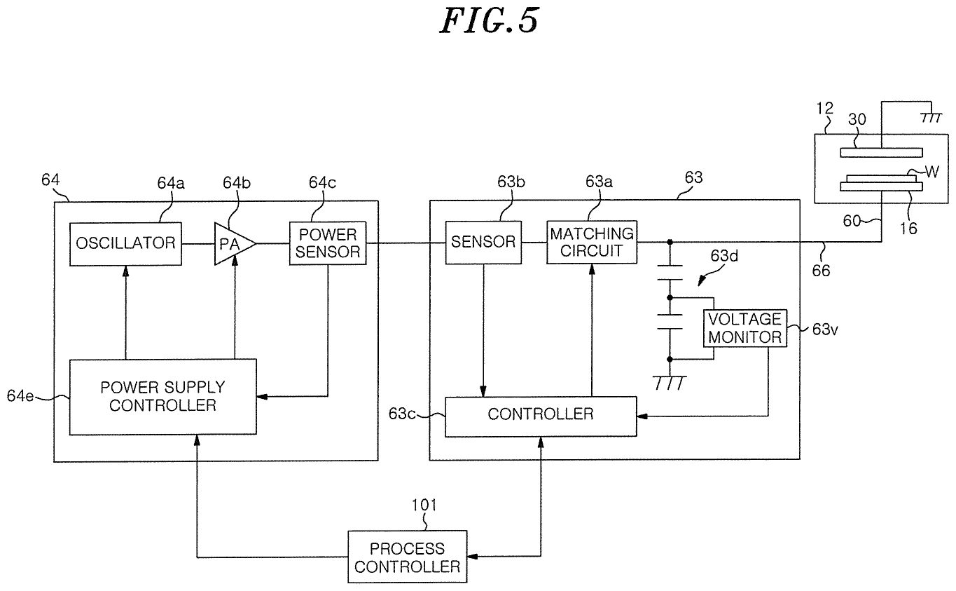

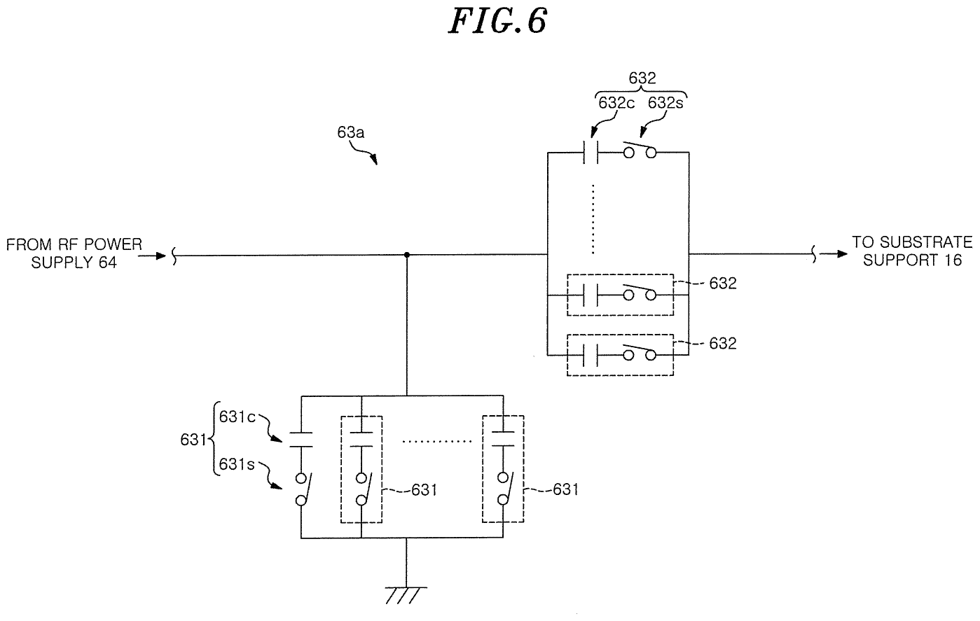

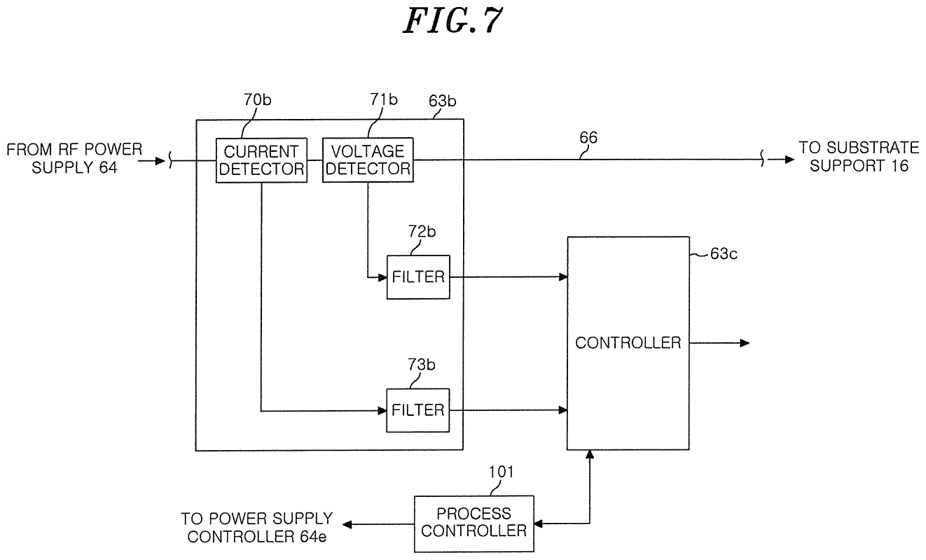

Next, a configuration of the matching unit 63 and a configuration of the RF power supply 64 according to the embodiment will be described. FIG. 5 shows an example of the configuration of the matching unit 63 and the configuration of the RF power supply 64 according to the embodiment. FIG. 6 shows an example of a matching circuit of the matching unit 63 according to the embodiment. FIG. 7 shows an example of a configuration of a sensor of the matching unit 63 according to the embodiment.

As shown in FIG. 5, the RF power supply 64 includes an oscillator 64a, a power amplifier (PA) 64b, a power sensor 64c, and a power supply controller 64e. The power supply controller 64e includes a processor such as a CPU. The power supply controller 64e controls the oscillator 64a and the power amplifier 64b by applying control signals to the oscillator 64a and the power amplifier 64b with a signal output from the process controller 101 and a signal output from the power sensor 64c.

Various control signals are sent from the process controller 101 to the power supply controller 64e. The signals sent from the process controller 101 to the power supply controller 64e include, for example, a second power level setting signal and a second frequency setting signal. The second power level setting signal specifies a power level of the RF bias power LF, and the second frequency setting signal specifies a set frequency of the RF bias power LF.

The RF power supply 64 changes the frequency of the RF bias power LF by changing the frequency of the oscillator 64a. The power supply controller 64e controls the oscillator 64a to output an RF signal having the set frequency specified by the second frequency setting signal. An output of the oscillator 64a is connected to an input of the power amplifier 64b. The RF signal output from the oscillator 64a is input to the power amplifier 64b. The power amplifier 64b amplifies the RF signal such that the RF bias power LF having the power level specified by the second power level setting signal is generated from the RF signal inputted thereto. The power amplifier 64b outputs the generated RF bias power LF.

The power sensor 64c is disposed at a rear stage of the power amplifier 64b. The power sensor 64c has a directional coupler, a traveling wave detector, and a reflected wave detector. In the power sensor 64c, the directional coupler outputs a part of a traveling wave of the RF bias power LF to the traveling wave detector and outputs a reflected wave thereof to the reflected wave detector. A signal for specifying the frequency of the RF bias power LF is output from the power supply controller 64e to the power sensor 64c. The traveling wave detector of the power sensor 64c generates a measurement value of a power level of a frequency component having the same frequency as the set frequency of the RF bias power LF among all frequency components of the traveling wave, that is otherwise referred to as a measurement value Pf21 of a power level of the traveling wave. The measurement value Pf21 is output to the power supply controller 64e for power feedback.

The reflected wave detector of the power sensor 64c generates a measurement value of a power level of a frequency component having the same frequency as the set frequency of the RF bias power LF among all frequency components of the reflected wave, that is otherwise referred to as a measurement value Pr21 of the power level of the reflected wave. Further, the reflected wave detector of the power sensor 64c generates a measurement value of a total power level of all frequency components of the reflected wave, which is otherwise referred to as a measurement value Pr22 of a power level of the reflected wave. The measurement value Pr21 is output to the process controller 101 to be displayed on a monitor. The measurement value Pr22 is output to the power supply controller 64e for protection of the power amplifier 64b.

The matching unit 63 includes a matching circuit 63a, a sensor 63b, a controller 63c, a voltage divider circuit 63d, and a voltage monitor 63v. The matching circuit 63a is an electronically controlled matching circuit. As shown in FIG. 6, the matching circuit 63a has a plurality of series circuits 631 and a plurality of series circuits 632.

The series circuits 631 are connected in parallel to each other. In the example shown in FIG. 6, the series circuits 631 are connected in parallel between a ground and a node between the RF power supply 64 and the electrode of the load side (the lower electrode). Each of the series circuits 631 includes a capacitor 631c and a switching element 631s. The capacitor 631c and the switching element 631s are connected in series. The switching element 631s is, for example, a PIN diode.

The series circuits 632 are connected in parallel to each other. In the example shown in FIG. 6, the series circuits 632 are connected in parallel between the RF power supply 64 and the electrode of the load side (the lower electrode). Alternatively, the series circuits 632 may be connected in parallel between the ground and a node between the RF power supply 64 and the electrode of the load side (the lower electrode). Each of the series circuits 632 includes a capacitor 632c and a switching element 632s. The capacitor 632c and the switching element 632s are connected in series. The switching element 632s is, for example, a PIN diode. The matching circuit 63a may further include an inductor or the like.

Referring back to FIG. 5, the controller 63c includes, for example, a processor. The controller 63c is operated under the control of the process controller 101. The controller 63c uses the measurement value output from the sensor 63b.

As shown in FIG. 7, the sensor 63b includes a current detector 70b, a voltage detector 71b, a filter 72b, and a filter 73b. The voltage detector 71b detects a voltage waveform of the RF bias power LF transmitted on the power feeding line 66, and outputs a voltage waveform analog signal indicating the corresponding voltage waveform. This voltage waveform analog signal is input to the filter 72b. The filter 72b generates a voltage waveform digital signal by digitizing the voltage waveform analog signal input thereto. Then, the filter 72b generates a voltage waveform signal by extracting, from the voltage waveform digital signal, only a frequency component corresponding to the set frequency of the RF bias power LF specified by the signal output from the process controller 101. The voltage waveform signal generated by the filter 72b is output to the controller 63c. The filter 72b may be implemented by, for example, an FPGA.

The current detector 70b detects a current waveform of the RF bias power LF transmitted on the power feeding line 66, and outputs a current waveform analog signal indicating the corresponding current waveform. This current waveform analog signal is input to the filter 73b. The filter 73b generates a current waveform digital signal by digitizing the current waveform analog signal input thereto. Then, the filter 73b generates a current waveform signal by extracting, from the current waveform digital signal, only a frequency component corresponding to the set frequency of the RF bias power LF specified by the signal output from the process controller 101. The current waveform signal generated by the filter 73b is output to the controller 63c. The filter 73b may be implemented by, for example, an FPGA.

Referring back to FIG. 5, the controller 63c is configured to obtain an impedance of the load side of the RF power supply 64 (hereinafter, referred to as “impedance Z2”). The controller 63c controls the switching elements 631s and the switching elements 632s of the matching circuit 63a to closely match the obtained impedance Z2 with the output impedance (matching point) of the RF power supply 64.

The controller 63c obtains the impedance Z2 using the voltage waveform signal generated by the filter 72b and the current waveform signal generated by the filter 73b. Specifically, the controller 63c obtains the impedance Z2 by the following equation (2):

Z2=V2/I2 Equation (2).

In equation (2), V2 indicates a voltage specified by the voltage waveform signal generated by the filter 72b, and indicates a current specified by the current waveform signal generated by the filter 73b.

The controller 63c transmits the data of the obtained impedance Z2 to the process controller 101.

The matching unit 63 according to the embodiment is configured to rapidly change the impedance by electronically controlling ON/OFF of the switching elements 631s of the series circuits 631 and ON/OFF of the switching elements 632s of the series circuits 632. Accordingly, the matching unit 63 rapidly matches the impedance of the load side (e.g., the lower electrode side) of the RF power supply 64 with the output impedance of the RF power supply 64. Further, the matching unit 63 is configured to detect the impedance Z2.

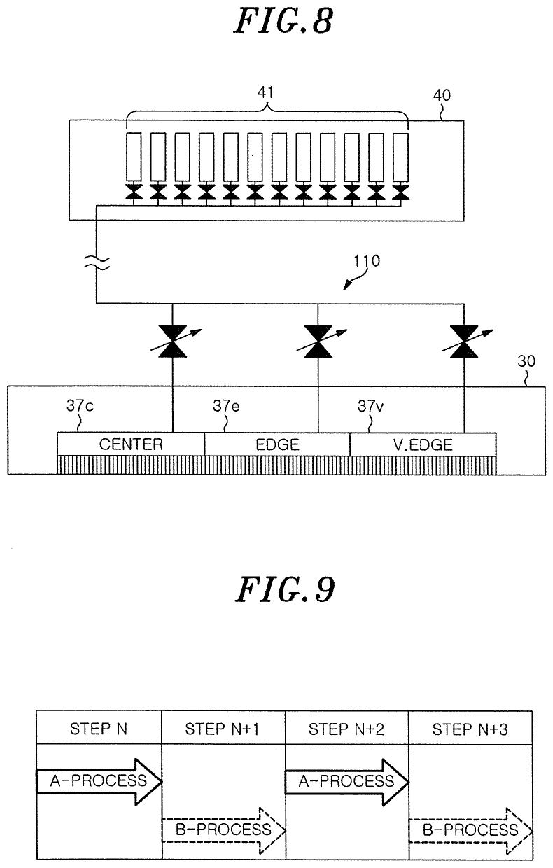

Next, a configuration of the gas supply system 110 according to the embodiment will be described. FIG. 8 shows an example of a schematic configuration of the gas supply system according to the embodiment. In the example of FIG. 8, the gas diffusion zones 37c, 37e, and 37v formed in the upper electrode 30 are illustrated in a simplified manner.

The gas box 40 has a gas source group 41 including various gas sources used for plasma processing such as plasma etching. The gas box 40 includes, for example, a valve and a flow controller (not shown) for each of the gas sources of the gas source group 41a. Further, the gas box 40 is configured to supply a single gas or a gas mixture of various gases as a processing gas depending on the plasma processing.

The gas supply system 110 distributes the processing gas supplied from the gas box 40 to be supplied to the gas diffusion zones 37c, 37e, and 37v.

Meanwhile, in the plasma processing apparatus 10, the switching of the processing gas supply and the switching of the RF power application are carried out to perform the plasma processing. For example, in the ALE method, a film forming process of depositing deposits on the wafer W and an etching process of etching the wafer W by activating the deposits are repeated to etch the wafer W.

FIG. 9 shows an example of schematic processes of the ALE method according to the embodiment. For example, in an A-process, deposits of a first processing gas are deposited on the wafer W. In a B-process, the wafer W is etched by a second processing gas. In the ALE method, the A-process and the B-process are repeated until a desired etching amount is obtained.

The gas supply system 110 according to the embodiment includes a plurality of supply paths for supplying the processing gas to the gas diffusion zones 37c, 37e, and 37v. The gas supply system 110 according to the embodiment has the same configuration as that disclosed in, e.g., Japanese Patent Application Publication No. 2020-4931 to stably and rapidly switch the processing gases.

However, in the plasma processing apparatus 10, switching of the supply of the processing gas is performed to start or stop the supplying of the processing gas, and a time lag exists between until the processing gas is actually supplied or stopped in the chamber after the switching. In the plasma processing apparatus 10, the processing gas passes through a space such as the gas diffusion space 37 of the upper electrode 30, and then is injected into the chamber 12 from the gas injection holes 34a.

In the plasma processing apparatus 10 according to the present embodiment, the impedance can be rapidly matched with the matching units 61 and 63, and the frequencies and the powers of the RF powers HF and LF supplied to the base 20 can be rapidly switched.

However, even in the gas supply system 110 capable of rapidly switching the processing gases as in the present embodiment, a time lag exists between the time when switching from the processing gas to another gas is performed and the time when the processing gas in the chamber 12 is actually switched to another processing gas. Therefore, it is difficult to synchronize the switching of the processing gas with the switching of the RF power.

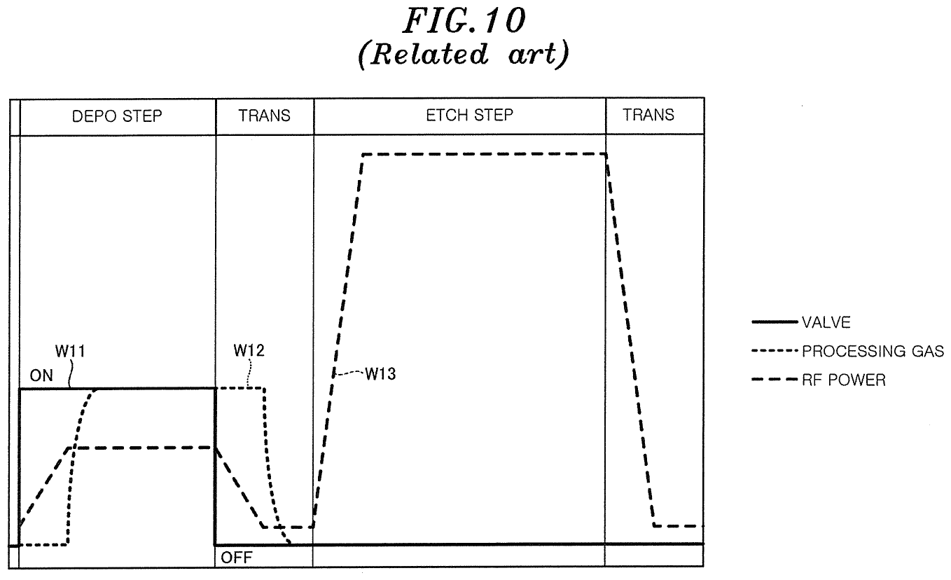

Accordingly, in the conventional ALE process, a buffering process for switching is provided between the film forming process and the etching process. FIG. 10 shows an example of the conventional ALE. FIG. 10 shows a film forming process (Depo Step) and an etching process (Etch Step). In the film forming process, the RF power is supplied at a first power level while supplying C₄H₆ gas and O₂ gas as processing gases. In the etching process, the RF power is supplied at a second power level higher than the first power level. FIG. 10 shows a waveform W11 of ON/OFF control of a valve for supplying the processing gas, a waveform W12 of the actually supplied processing gas, and a waveform W13 of the RF power.

In the conventional plasma processing apparatus, a machine-controlled matching unit is generally used as the matching units 61 and 63. The machine-controlled matching unit includes a capacitor that is driven by a motor to change a capacitance. In a machine-controlled matching unit, an impedance control speed is limited by a speed of controlling the capacitance of the capacitor by the motor. Therefore, the RF power has a time lag until the power is actually changed as shown in the waveform W13. The time lag of RF power can be considerably reduced by employing an electronically controlled matching unit similar to the matching units 61 and 63 according to the present embodiment using switching elements.

Further, although the supply of the processing gas is switched on or off in response to the film forming process as shown in the waveform W11, a time lag exists between the ON or OFF switching timing of the valve and the actual switching timing of the processing gas, as shown in the waveform W12. Therefore, it was difficult to synchronize the switching of processing gas with the switching of RF power. Accordingly, in the conventional ALE process, the buffering process (Trans) for switching is provided between the film forming process (Depo Step) and the etching process (Etch Step).

Therefore, in the present embodiment, the arrival time at which the processing gas reaches the chamber 12 after the start of the supply of the processing gas to the chamber 12 is calculated as follows.

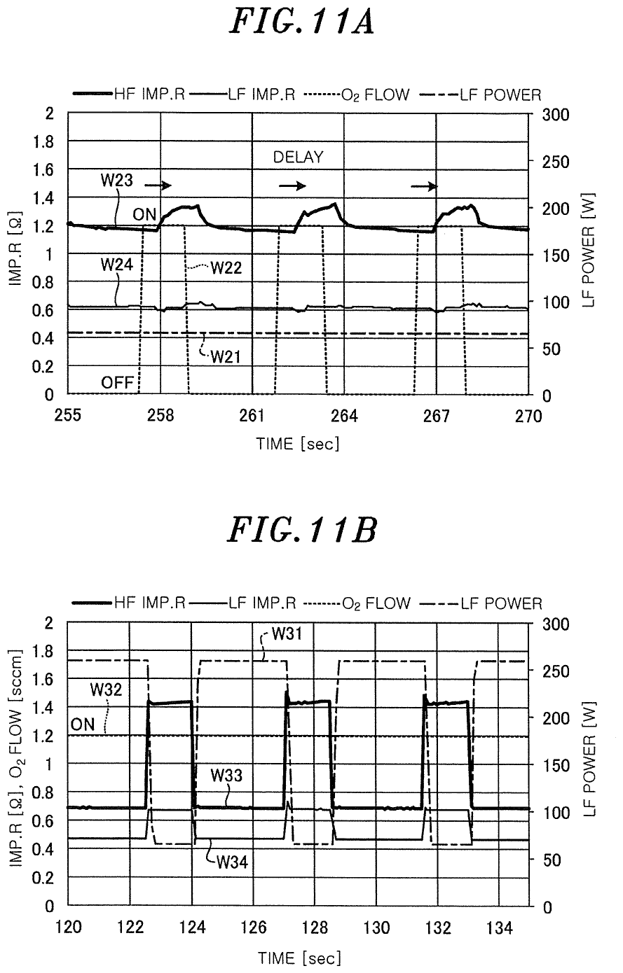

In the plasma processing apparatus 10, an impedance of the chamber 12 is changed depending on a change in the amount of the processing gas in the chamber 12. FIG. 11A shows an example of an impedance change. FIG. 11A shows the change in the impedance change in the case of switching ON/OFF of the supply of O₂ gas serving as the processing gas while supplying the RF bias power LF from the RF power supply 64 at a constant power level. FIG. 11A shows a waveform W21 indicating the power level (LF Power) of the RF bias power LF and a waveform (O₂ flow) W22 indicating ON/OFF of the valve for supplying the processing gas (O₂ gas). Further, FIG. 11A shows a waveform W23 of a real part (HF Imp.R) of the impedance Z1 detected by the matching unit 61 and a waveform W24 of a real part (LF Imp.R) of the impedance Z2 detected by the matching unit 63. The impedances Z1 and Z2 are changed as shown in the waveforms W23 and W24 depending on the ON/OFF of the supply of the processing gas (O₂ gas) shown in the waveform W22. For example, when the supply of the processing gas (O₂ gas) is switched on, the impedances Z1 and Z2 are increased. Particularly, as shown in the waveform W23, the impedance Z2 of the RF power supply 64 for outputting the RF bias power LF for bias is changed considerably.

FIG. 11B shows an example of an impedance change. FIG. 11B shows the impedance change in the case of switching ON/OFF of the supply of the RF bias power LF at a constant power level from the RF power supply 64 while supplying a constant amount of O₂ gas as the processing gas. FIG. 11B shows a waveform W31 indicating the power level (LF Power) of the RF bias power LF and a waveform (O₂ Flow) W32 indicating the supply amount of the processing gas (O₂ gas). Further, FIG. 11B shows a waveform W33 of a real part (HF Imp.R) of the impedance Z1 detected by the matching unit 61 and a waveform W34 of a real part (LF Imp.R) of the impedance Z2 detected by the matching unit 63. When the processing gas (O₂ gas) is supplied to the chamber 12 at a constant amount as shown in the waveform W32, the impedances Z1 and Z2 are changed in synchronization with the ON/OFF of the RF bias power LF and is substantially constant during the ON period of the RF bias power LF, as shown in the waveforms W31, W33 and W34. This may be because the amount of the processing gas in the chamber 12 is maintained at a substantially constant level by supplying the processing gas to the chamber 12 at a constant amount.

As shown in FIG. 11A, in the plasma processing apparatus 10, when the processing gas is supplied into the chamber 12, the impedance of the chamber 12 is changed after a certain delay. Therefore, the arrival time at which the processing gas reaches the chamber 12 after the start of the supply of the processing gas into the chamber 12 is calculated based on a time period from a timing at which ON/OFF of the valve for supplying the processing gas is switched to a timing at which the impedance waveform is changed.

For example, an operator performs pre-processing for calculating the arrival time when the ALE is about to start on the wafer W using the plasma processing apparatus 10. The pre-processing may be performed by switching the ON/OFF of the supply of the processing gas while supplying the RF power(s) from one or both of the RF power supply 62 and the RF power supply 64. The pre-processing may be the same as the actual substrate processing such as ALE for the wafer W. Alternatively, the pre-processing may be a dedicated process for calculating the arrival time. For example, as shown in FIG. 11A, the pre-processing may be a process of switching the ON/OFF of the supply of the processing gas while supplying the RF bias power LF at a constant power level from the RF power supply 64.

The matching units 61 and 63 detect the impedance of the chamber 12 during the pre-processing. The matching units 61 and 63 transmit the detected impedance data to the process controller 101.

The deriving unit 101a of the process controller 101 detects the impedance of the chamber 12 using the matching units 61 and 63 and controls the gas box 40 and the gas supply system 110 to start the supply of the processing gas to the chamber 12. Then, based on the impedance change detected by the matching units 61 and 63, the deriving unit 101a calculates the arrival time at which the processing gas reaches the chamber 12 after the supply of the processing gas to the chamber 12 is started.

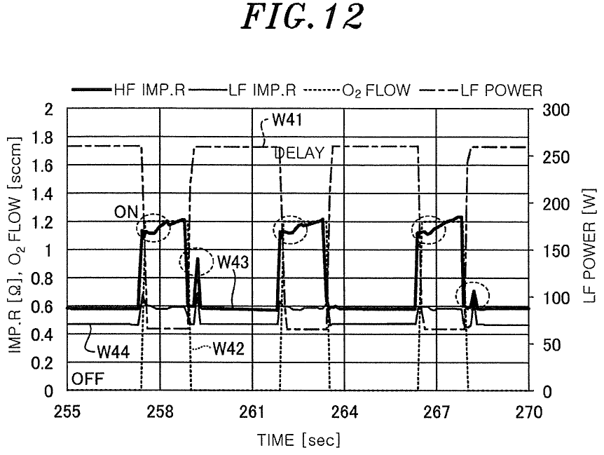

FIG. 12 shows an example of an impedance change. FIG. 12 shows the impedance change in the case of switching the ON/OFF of the supply of O₂ gas serving as the processing gas while switching the ON/OFF of the RF bias power LF having a constant power level supplied from the RF power supply 64, as in the case of ALE. FIG. 12 shows a waveform W41 indicating the power level (LF Power) of the RF bias power LF and a waveform (O₂ flow) W42 indicating the supply amount of the processing gas (O₂ gas). Further, FIG. 12 shows a waveform W43 of a real part (HF Imp.R) of the impedance Z1 detected by the matching unit 61 and a waveform W44 of a real part (LF Imp.R) of the impedance Z2 detected by the matching unit 63. In FIG. 12, the ON/OFF of the valve for supplying the processing gas and the ON/OFF of the RF bias power LF are synchronized. As shown in the waveforms W43 and W44, the impedances Z1 and Z2 are changed when the processing gas is supplied into the chamber 12. For example, when the supply of the processing gas is switched on, the impedance Z2 is gradually increased after a certain delay. The deriving unit 101a calculates the time period from after the supply of the processing gas is switched on until the waveform of the impedance Z2 is changed. For example, the deriving unit 101a measures the time period from the time at which the supply of the processing gas is switched on until the time at which the impedance Z2 is increased by a predetermined value or more from the impedance that is measured when the impedance Z2 is switched on. Then, the deriving unit 101a calculates the measurement time as the arrival time.

The correction unit 101b corrects a supply timing of the processing gas based on the calculated arrival time. For example, the correction unit 101b stores the calculated arrival time in the storage unit 103 as correction information. The correction unit 101b corrects the supply timing of the processing gas based on the correction information stored in the storage unit 103. For example, the storage unit 103 stores, as the recipe, the information related to the type of the processing gas used in the ALE, the switching timing of the processing gas, the switching timing of the RF power HF and the RF bias power LF, and the like. The correction unit 101b corrects the switching timing of the processing gas stored in the recipe to be advanced by the amount of the arrival time of the correction information.

The supply timing of the processing gas may be corrected by the operator or the like. For example, the calculated arrival time may be displayed on the user interface 102, and the operator may correct the supply timing of the processing gas of the recipe based on the displayed arrival time.

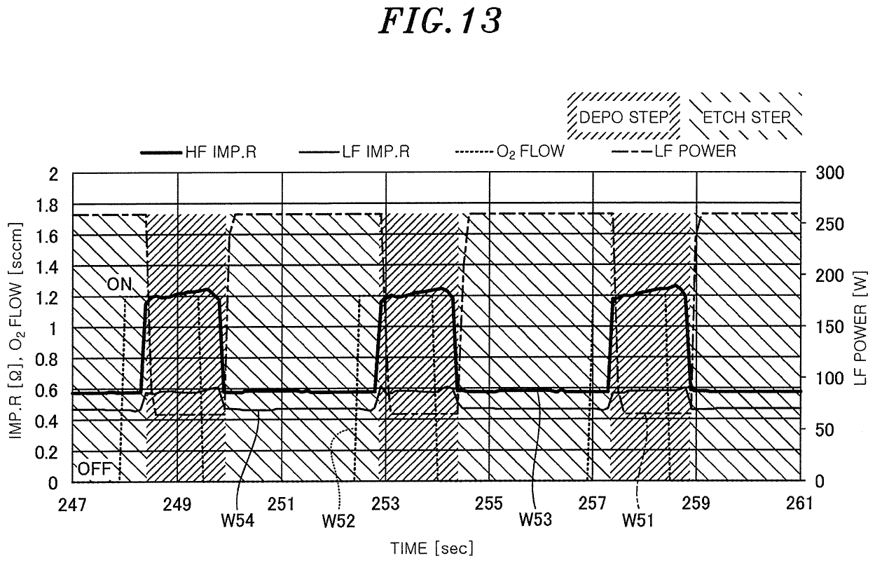

FIG. 13 shows an example of the correction of the supply timing of the processing gas according to the embodiment. FIG. 13 shows the case of correcting the supply timing of the processing gas shown in FIG. 12. FIG. 13 shows a waveform W51 indicating the power level (LF Power) of the RF bias power LF and a waveform W52 indicating the supply amount (O₂ Flow) of the processing gas. As shown in the waveform W52, the ON/OFF switching timing of the valve is advanced by the amount of the arrival time. Further, FIG. 13 shows a waveform W53 of a real part (HF Imp.R) of the impedance Z1 detected by the matching unit 61 and a waveform W54 of a real part (LF Imp.R) of the impedance Z2 detected by the matching unit 63. Further, FIG. 13 shows a film forming process (Depo Step) and an etching process (Etch Step). Referring to FIG. 13, as shown in the waveform W54, the impedance Z2 is increased at the time when the film forming process is started, which indicates that the processing gas reaches the chamber 12 and the switching timing of the processing gas and the switching (timing) of the RF power HF and the RF bias power LF are synchronized.

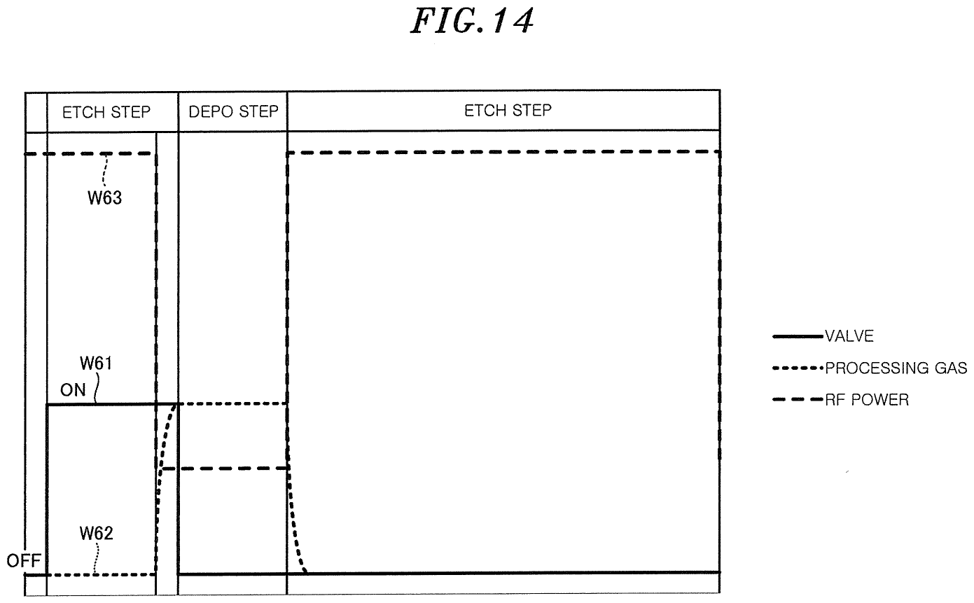

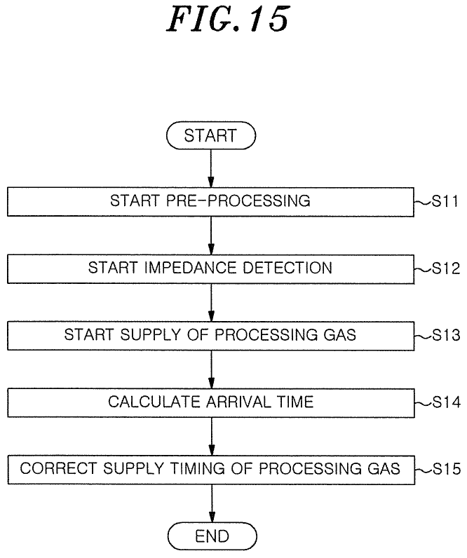

FIG. 14 shows an example of the correction of the supply timing of the processing gas according to the embodiment. FIG. 14 shows the case of correcting the supply timing of the processing gas for ALE. FIG. 14 shows a film forming process (Depo Step) and an etching process (Etch Step). In the film forming process, C₄H₆ gas and O₂ gas are supplied as the processing gas, and the RF power is supplied at a first power level. In the etching process, the RF power is supplied at a second power level higher than the first power level. FIG. 14 shows a waveform W61 of ON/OFF control of the valve for supplying the processing gas, a waveform W62 of the processing gas being actually supplied, and a waveform W63 of the RF power. As shown in the waveform W61, the timing of ON/OFF switching of the valve corrected to be advanced from the start of the film forming process by the amount of the arrival time. Accordingly, the switching of processing gas and the switching of RF power can be synchronized.

Further, the processing time of ALE can be shortened by synchronizing the switching of the processing gas and the switching of the RF power. For example, in the conventional ALE process shown in FIG. 10, a buffering process (Trans) for switching is provided between the film forming process and the etching process. For example, in the conventional ALE process shown in FIG. 10, a buffering process with a margin is provided for 2 seconds or more when the processing gas is switched.

On the other hand, in the ALE shown in FIG. 14, the buffering process for switching between the film forming process and the etching process may be omitted because it becomes unnecessary by synchronizing the switching of the processing gas and the switching of the RF power. Accordingly, the processing time can be shortened.

Since the switching of the processing gas and the switching of the RF power can be synchronized, the time period for the film forming process or the time period for the etching process can be shortened. Further, since the switching of the processing gas and the switching of the RF power can be synchronized, the power level of the RF power can be reduced to a low power level (e.g., about 750 W) that was conventionally not allowable. In the ALE, it is possible to finely control the amount of deposits and perform an even thinner etching by shortening the time period for the film forming process or the time period for the etching process or by reducing the power level of RF power.

(Correction Method)

Next, an example of a control sequence of a correction method in which the plasma processing apparatus 10 corrects a supply timing of the processing gas will be described. FIG. 15 shows an example of the control sequence of the correction method according to the embodiment.

The process controller 101 controls the plasma processing apparatus 10 to start the pre-processing for calculating the arrival time (step S11). In the pre-processing, the pressure in the chamber 12 is reduced to a desired vacuum level. Further, in the pre-processing, the RF power(s) is supplied from one or both of the RF power supply 62 and the RF power supply 64.

The plasma processing apparatus 10 starts the detection of the impedance of the chamber 12 during the pre-processing using the matching units 61 and 63 (step S12). The matching units 61 and 63 transmit the detected impedance data to the process controller 101.

The process controller 101 controls the gas box 40 and the gas supply system 110 to start a supply of the processing gas into the chamber 12 (step S13).

The deriving unit 101a of the process controller 101 calculates, based on the detected impedance change, the arrival time at which the processing gas reaches the chamber 12 after the supply of the processing gas to the chamber 12 is started (step S14). For example, the deriving unit 101a measures a time period from the time at which the supply of the processing gas is switched on until the time at which the impedance is increased by a predetermined value or more from the impedance that is measured when the impedance Z2 is switched on. Then, the deriving unit 101a calculates the measurement time as the arrival time.

The correction unit 101b of the process controller 101 corrects the supply timing of the processing gas based on the calculated arrival time (step S15). Then, the process is terminated. For example, the correction unit 101b corrects the switching timing of the processing gas to be advanced by the amount of the arrival time.

As described above, the correction method according to the present embodiment includes: the step (step S12) of starting the detection of the impedance of the chamber 12 having therein the substrate support 16 on which the wafer W (substrate) is placed; the step (step S13) of starting the supply of the processing gas; and the step (step S14) of calculating the arrival time at which the processing gas reaches the chamber 12 from the start of the supply of the processing gas toward the chamber 12. Accordingly, the correction method according to the present embodiment can calculate the arrival time at which the processing gas reaches the chamber 12 after the start of the supply of the processing gas toward the chamber 12.

The correction method according to the present embodiment further includes the step (step S15) of correcting the timing of starting the supply of the processing gas based on the calculated arrival time. Accordingly, the correction method according to the present embodiment can synchronize the switching of the processing gas and the switching of the RF power.

Further, the plasma processing apparatus 10 according to the present embodiment includes the chamber 12, the gas box 40 and the gas supply system 110 (gas supply unit), the matching units 61 and 63 (detection unit), and the deriving unit 101a. The chamber 12 has therein the substrate support 16 on which the wafer W (substrate) is placed. The gas box 40 and the gas supply system 110 supply the processing gas to the chamber 12. The matching units 61 and 63 detect the impedance of the chamber 12. The deriving unit 101a controls the gas box 40 and the gas supply system 110 to start the supply of the processing gas into the chamber 12 while detecting the impedance of the chamber 12 using the matching units 61 and 63, and calculates the arrival time at which the processing gas reaches the chamber 12 from the start of the supply of the processing gas toward the chamber 12 based on the impedance change detected by the matching units 61 and 63. Accordingly, the plasma processing apparatus 10 according to the present embodiment can calculate the arrival time at which the processing gas reaches the chamber 12 after the start of the supply of the processing gas toward the chamber 12.

The presently disclosed embodiments are considered in all respects to be illustrative and not restrictive. The above-described embodiments can be embodied in various forms. Further, the above-described embodiments may be omitted, replaced, or changed in various forms without departing from the scope of the appended claims and the gist thereof.

For example, in the above-described embodiments, the case where the ALE process is performed by switching the supply of the processing gas and switching the application of the RF power has been described as an example. However, the present disclosure is not limited thereto, and any process may be performed as long as it is preferable to synchronously switch the supply of processing gas and the application of RF power. For example, the present disclosure may be applied to the ALD (atomic layer deposition) process.

Further, in the above-described embodiments, the case where the timing of starting the supply of the processing gas is corrected based on the calculated arrival time has been described as an example. However, the present disclosure is not limited thereto, and the timing of starting the supply of RF power to the substrate support 16 may be corrected based on the calculated arrival time. For example, the correction unit 101b corrects the timing of supplying the RF power to the substrate support 16 to be delayed by the amount of the arrival time. In this case as well, the switching of the processing gas and the switching of the RF power can be synchronized.

Further, in the above-described embodiments, the case where the pre-processing for calculating the arrival time is performed before the start of the ALE process for the wafer W has been described as an example. However, the present disclosure is not limited thereto, and it is possible to detect the impedance during the ALE process and calculate the arrival time based on a time period from the timing of switching the ON/OFF of the valve for supplying the processing gas until when the impedance waveform is changed. Then, the timing of starting the supply of the processing gas or the timing of starting the supply of the RF power to the substrate support 16 may be corrected based on the calculated arrival time. In other words, the plasma processing apparatus 10 may detect the arrival time during the ALE process and perform feedback control for correcting the timing of starting the supply of the processing gas or the timing of starting the supply of RF power to the substrate support 16 based on the detected arrival time.

In the above-described embodiments, the case where the timing at which the impedance Z2 is increased by a predetermined value or more is detected as the timing at which the processing gas reaches the chamber 12 has been described as an example. However, the present disclosure is not limited thereto. For example, the timing at which the amount of change in the impedance Z2 becomes greater than or equal to a predetermined amount of change may be detected as the timing at which the processing gas reaches the chamber 12. For example, when the timing at which the chamber 12 is filled with the processing gas is set to the timing at which the processing gas reaches the chamber 12, the timing at which the amount of change in the impedance Z2 becomes stable after the impedance Z2 is changed may be detected as the timing at which the processing gas reaches the chamber 12.

Further, in the above-described embodiments, the case where the plasma processing apparatus 10 is the plasma etching apparatus has been described as an example. However, the present disclosure is not limited thereto, and the plasma processing apparatus 10 may be a film forming apparatus for forming a film using plasma or a modification apparatus for modifying a film quality or the like.

Further, in the above-described embodiments, the case where the plasma etching is performed as the plasma processing has been described as an example. However, the present disclosure is not limited thereto, and the plasma processing may be any processing using plasma.

Further, in the above-described embodiments, the case where the substrate is the wafer W has been described as an example. However, the present disclosure is not limited thereto, and the substrate may be any substrate such as a glass substrate or the like.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made departing from the spirit of the disclosures. The accompanying claims and their equivalents are intended to cover such forms or modifications as would fall within the scope and spirit of the disclosures.

1. A correction method comprising:
starting a detection of an impedance of a chamber having therein a substrate support on which a substrate is placed;
starting a supply of a processing gas into the chamber; and
calculating an arrival time at which the processing gas reaches the chamber from a start of the supply of the processing gas to the chamber based on a change in the detected impedance.

2. The correction method of claim 1, further comprising:
correcting a timing of starting the supply of the processing gas based on the calculated arrival time.

3. The correction method of claim 1, further comprising:
correcting a timing of starting a supply of an RF power to the substrate support based on the calculated arrival time.

4. A plasma processing apparatus comprising:
a chamber having therein a substrate support on which a substrate is placed;
a gas supply unit configured to supply a processing gas into the chamber;
a detection unit configured to detect an impedance of the chamber; and
a deriving unit is configured to control the gas supply unit and the detection unit to start the supply of the processing gas from the gas supply unit into the chamber while detecting the impedance of the chamber using the detection unit and to calculate an arrival time at which the processing gas reaches the chamber from the start of the supply of the processing gas to the chamber based on a change in the impedance detected by the detection unit.
